(19) United States
(12) Patent Application Publication
(10) Pub. No.: US 2016/0153084 A1
(43) Pub. Date: Jun. 2, 2016

(54) CERAMIC DIELECTRIC FILMS, METHOD FOR MAKING CERAMIC DIELECTRIC FILMS

(71) Applicants: Beihai Ma, Naperville, IL (US); Uthamalingam Balachandran, Willowbrook, IL (US); Stephen E. Dorris, LaGrange Park, IL (US); Tae H. Lee, Naperville, IL (US)

(72) Inventors: Beihai Ma, Naperville, IL (US); Uthamalingam Balachandran, Willowbrook, IL (US); Stephen E. Dorris, LaGrange Park, IL (US); Tae H. Lee, Naperville, IL (US)

(73) Assignee: UCHICAGO ARGONNE, LLC, Chicago, IL (US)

(21) Appl. No.: 14/489,153

(22) Filed: Sep. 17, 2014

(51) Int. Cl. C23C 14/22; C23C 14/06

(52) U.S. Cl. CPC C23C 14/22; C23C 14/06

(57) ABSTRACT

The invention provides a dielectric-conductive substrate construct comprising a conductive material having a first surface and a second surface, and a dielectric film directly contacting the first surface and substantially covering the first surface, wherein the second surface is exposed to the ambient environment. Also provided is a method for producing a two component dielectric-conductive substrate, the method comprising supplying a base metal; and directly contacting a ceramic to the base metal to form a ceramic-metal interface while simultaneously preventing the formation of electrically insulative layers at the interface.

### CONTRACTUAL ORIGIN OF THE INVENTION

The U.S. Government has rights in this invention pursuant to Contract No. DE-AC02-06CH11357 between the U.S. Department of Energy and UChicago Argonne, LLC, representing Argonne National Laboratory.

### BACKGROUND OF THE INVENTION

1. Field of the Invention

This invention relates to ceramic dielectric films and more specifically, this invention relates to flexible ceramic films and a method for making ceramic films on polymers, metals and metal alloy foils.

2. Background of the Invention

The demand for power electronic devices continues to explode. For example, production of hybrid vehicles, pure electric vehicles and other forms of electrified transportation required $364 million worth of power electronic components in 2011. In 2020, the demand is estimated to be 10 times that or about $3.6 billion.

The development of power electronic devices is progressing towards improved performance, increased reliability, reduced size and weight. However, with this increased performance and reduced size comes increased operating temperatures. The performance and lifetime of capacitors available today degrade rapidly with increasing temperature. For example, ripple current capability decreases when temperatures increase from 85° C. to 105° C.

Efforts to produce improved capacitors have yielded mixed results. When dielectric is directly deposited on metal, dielectric and ferroelectric properties suffer. This is due to the formation of cubic non-ferroelectric layers at the metal/dielectric interface.

When an oxide layer is interposed between the metal and dielectric layers, dielectric capacity improves, but at considerable fabrication costs. This is partly due to the added fabrication steps required. Also, more expensive noble metals must be utilized with oxide films inasmuch as base metals would oxidize or otherwise react with the films.

A need exists in the art for a method for producing and depositing dielectric film that exhibits high dielectric constants at high bias voltages. The method should enable deposition of dielectric directly on metal without the need for extra processing or constituents between the dielectric and metal. The resulting construct should exhibit dielectric properties at least as high as 80.

### SUMMARY OF INVENTION

An object of the invention is to provide a method for producing ceramic-conductor constructs that overcomes many of the disadvantages of the prior art.

Another object of the invention is to provide a method for producing ceramic films on substrate. A feature of the invention is the direct application of ceramic films on substrate. An advantage of this method is that it produces high-dielectric-constant (high K) constructs.

Still another object of the present invention is to provide a method to replace the currently used low-K polymer dielectric component of capacitors with relatively high (K>80) components. A feature of the method is directly contacting ceramic material to flexible substrates such as aluminum foil, amorphous materials, crystalline materials, generally conductive materials, etc, to produce a construct. Another feature of the method is that no support structure is required during fabrication of the construct. An advantage of the method is that thicknesses of the dielectric material are minimized, therefore the capacitance density of a capacitor incorporated into the construct is maximized.

Yet another object of the present invention is to provide a method for producing a two-component dielectric construct. A feature of the method is that it minimizes the production of detrimental cubic non-ferroelectric layers between the two components. An advantage of the method is that the two-component construct exhibits dielectric values greater than 80 (and often greater than 100), which is higher than state of the art two-component systems, but also less expensive than multi component constructs which incorporate intercalated oxide layers.

Briefly, the invention provides a dielectric-conductive substrate construct comprising: a conductive material having a first surface and a second surface; a dielectric film directly contacting the first surface and substantially covering the first surface, wherein the second surface is exposed to the ambient environment.

Also provided is a method for producing a dielectric-conductive substrate, the method comprising supplying a base metal; and directly contacting a ceramic to the base metal to form a ceramic-metal interface while simultaneously preventing the formation of electrically insulative layers at the interface.

### BRIEF DESCRIPTION OF DRAWING

The invention together with the above and other objects and advantages will be best understood from the following detailed description of the preferred embodiment of the invention shown in the accompanying drawings, wherein:

FIG. 1 is a schematic depiction of two embodiments of dielectric sheets, in accordance with features of the present invention;

FIG. 2 is a schematic of an aerosol deposition process, in accordance with features of the present invention;

FIG. 3 is schematic of a reel-to-reel process for fabrication of long-length ceramic dielectric sheets by aerosol deposition, in accordance with features of the present invention, and

FIG. 4 are graphs depicting dielectric properties as a function of bias field, in accordance with features of the present invention. FIG. 4A is a graph depicting dielectric properties as a function of bias field measured in PLZT films deposited by aerosol deposition on platinized silicon substrate. FIG. 4B is a graph depicting dielectric properties as a function of bias field measured in PLZT films deposited by aerosol deposition on aluminum foil.

### DETAILED DESCRIPTION OF THE INVENTION

The foregoing summary, as well as the following detailed description of certain embodiments of the present invention, will be better understood when read in conjunction with the appended drawings.

As used herein, an element or step recited in the singular and preceded with the word “a” or “an” should be understood as not excluding plural said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

The inventors have devised a method for utilizing high-dielectric-constant (high K) ceramics to replace the currently used low-K polymer dielectric components in power electronic devices. For example, the utilization of PLZT (lead-lanthanum-zirconate-titanate) ceramic confers the high K properties of constructs produced via the invented method.

An embodiment of the method utilizes aerosol deposition done at room temperature (for example between about 20° and about 30° C. and preferably between about 23° C. and about 27° C.). The method allows application of dielectric films on a variety of substrates, including, but not limited to polymers, amorphous material (e.g. glass), crystalline material, conductive material (such as ferrous and nonferrous metals), and a combination of such substrates. Further, the inventors envision using different base substrates simultaneously, overlaid with the same dielectric layer. Alternatively, the inventions envision using electrically conductive wires embedded in different base substrates, then overlaid with the same dielectric layer.

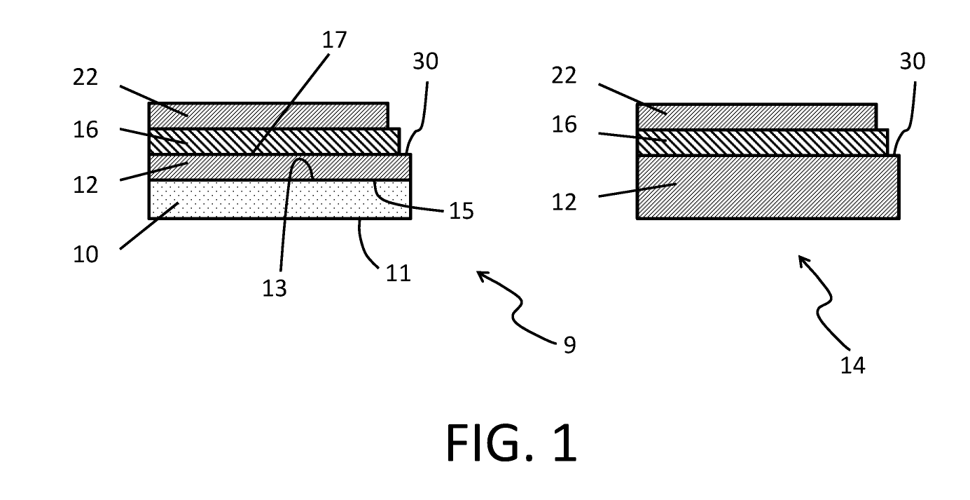

FIG. 1 shows schematic cross sectional views of ceramic dielectric sheets fabricated via the invented method. FIG. 1 depicts a first embodiment, designated as numeral 9. This embodiment is comprised of a polymer film (or other flexible support substrate) 10 as a flexible foundation or support structure. The support structure has a first downward facing surface 11 and a second, upwardly facing surface 13.

The upwardly facing surface 13 is laminated, overlaid or otherwise covered with a metal film 12, that metal film defining a bottom electrode with a first (in this case downwardly facing) surface 15 and a second (upwardly facing) surface 17. A ceramic dielectric film 16 is subsequently deposited on that metal film. Then, another metal film 22 substantially covers the dielectric film 16.

A second embodiment of the invention 14 does not contain a flexible support substrate (element number 10 of the first embodiment 9 shown in FIG. 1). A salient feature of a second embodiment 14 of the invention is the overlaying of dielectric material directly onto a support substrate, for example without the need for a primer coat or oxide film interposed between the dielectric material and the substrate. The substrates can be flexible, and capable of achieving a radius of curvature of about 5 millimeters. These curvatures enable the roll-to-roll process of the inventors' earlier filed U.S. patent application Ser. No. 62/012,857 (the entirety of which is incorporated herein by reference) but without the underlying polymeric flexible substrate required therein.

Rather, the instant invented method enables direct deposition of ceramic onto flexible electrically conductive substrate, the substrate serving as a self-supporting electrode as depicted as the second embodiment 14 of FIG. 1. The self-supporting nature of the construct is to be construed herein, such that no underlying support structure is required either during fabrication of the construct, production (such as rolling or other assembly) of a resulting capacitor or product incorporating the construct, or actual use of the resulting product.

The elimination of the flexible support substrate (that missing substrate being element 10 of the first embodiment 9 shown in FIG. 1) confers high volumetric and gravimetric efficiencies. The elimination of the flexible support confers approximately a 25 percent reduction in volume compared to embodiments utilizing flexible supports. As shown by the second embodiment 14 of FIG. 1, an embodiment of the invention comprises a base metal (e.g. Al, Cu, Ni) foil 12 as the support substrate as well as the bottom or first electrode. Dense (e.g., approximately less than 5 percent porosity) ceramic film 16 is subsequently formed over substantially all of at least one surface of the foil 12. Optionally, ceramic film is deposited on both surfaces of the foil. Finally, another metal film 22 is deposited on the ceramic dielectric, this second metal film defining a second (in this instance, the top) electrode.

A myriad of substrates 10 (shown by the first embodiment 9 of FIG. 1) are suitable, including but not limited to polymer, amorphous material such as glass, crystalline material such as metals, ceramics, silicon, and combinations thereof, ferrous material such as iron, steel, and nonferrous material such as aluminum, copper and zinc, their alloys, and combinations thereof.

Electrode material can be any electrically conductive substrate, such as base metal (Al, Cu, Ni, Zn, and alloys thereof), metalized silicon or other semi-conductor material, and combinations thereof.

A myriad of materials are suitable as a dielectric. In an embodiment, the dielectric film deposited and utilized is a ceramic selected from the group consisting of perovskites having a general formula ABO₃, lead zirconate titanate, lanthanum doped lead zirconate titanate, lead magnesium niobate, barium titanate, barium strontium titanate, and combinations thereof. Preferred dielectric materials include, but are not limited to, PLZT, PZT, BaTiO₃, (Ba, Sr)TiO₃, and combinations thereof.

Typical thickness of polymer film is about 2 to about 10 microns (μm). Typical thickness of metal foil is about 5 to about 20 μm. Bottom electrode thicknesses range from between about 0.01 to about 0.5 μm. Dielectric film thicknesses range from about 1 to about 10 μm. Top electrode thicknesses range from about 0.01 to about 0.5 μm. In instances where the bottom electrode also serves as the support substrate, its thickness is greater than the top electrode thickness.

### Fabrication

### Detail

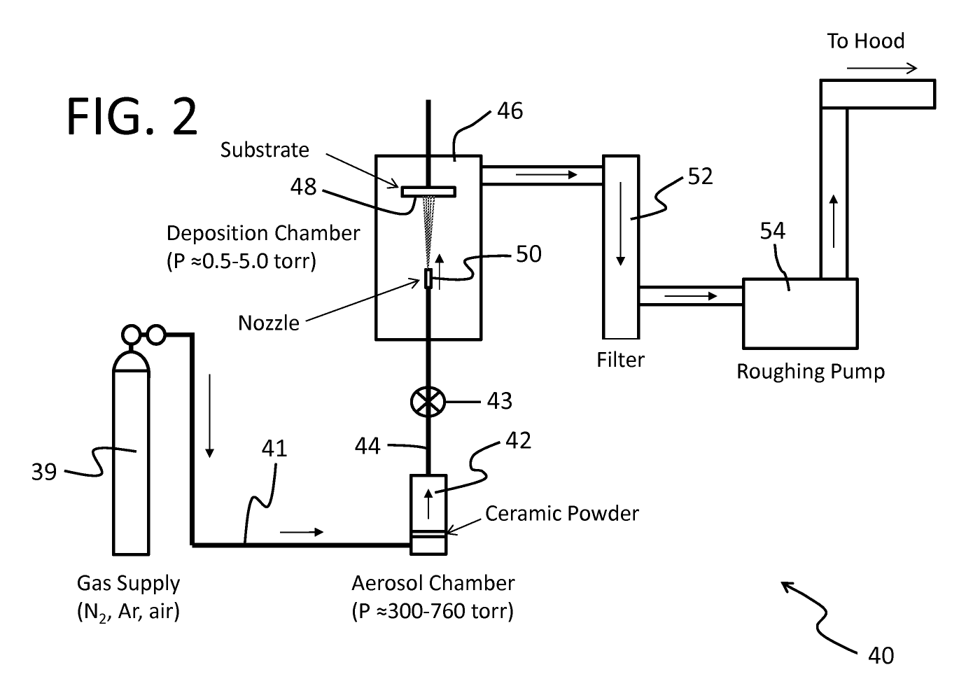

A feature of the invented method is the incorporation of aerosol deposition (AD) at room temperature, the method scalable for mass production. In an embodiment of the AD process (depicted in FIG. 2), an aerosol of a ceramic powder is generated in a chamber 42 maintained in a pressure range of between about 300 torr and about 760 torr. Such pressures are attained and maintained via a first conduit 41 establishing fluid communication between the first chamber 42 and a pressurized gas source 39. The material being deposited will dictate the constituency of the gas. FIG. 2 depicts relatively inert gases (e.g., N₂, Ar and Air) being utilized, while other gases not reactive with the ceramic powder and substrate are also suitable.

A means 44 for transporting the powder (such as a conduit) between the first chamber 42 and a second chamber 46, is positioned between the two chambers so as to establish fluid communication between the two chambers.

The second chamber serves as a deposition chamber wherein the particles impact the substrate to be coated by the particles. In an embodiment of the method, the second chamber 46 is kept at a pressure lower than the pressure maintained in the first chamber 42 so as to subject the particles comprising the powder to a rapid decompression. One way this decompression is effected is via a valve 43 positioned along the conduit 44 such that when the valve is opened, the particles comprising the powder rapidly enter the second chamber and impact the substrate 48. Another way is for a vacuum or pressure differential to pull the fluid through the system, that pressure differential effected via a roughing pump situated downstream, as depicted in FIG. 2. (The valve does not need to be present in this embodiment.) A suitable pressure for the second chamber is between about 1 torr and about 5 torr. This approximately 500 fold pressure differential accelerates the fine particles toward the substrate. However, pressure differentials of between 400-fold and 3000-fold are also suitable.

When the aforementioned high speed fine ceramic particles impact the substrate 48, they collide with the upstream surface of the substrate and with each other. The kinetic energy of those moving particles is substantially converted to thermal energy. This self-generating or internally derived thermal energy (e.g. heat) facilitates bonding (.e.g. fusing) between adjacent ceramic molecules and also between the particles and the substrate without the need for externally derived heat. As such, the invention eliminates the need for high temperature sintering, such as prior art sintering and anneal processes which require externally provided heating sources to achieve temperatures above approximately 800° C.

A conformal, defect-free film of dielectric results over substantially the entire upstream surface of the substrate.

Optionally, and to control deposition of the particles on the substrate 48, a nozzle 50 is positioned upstream of the substrate surface to be coated, the nozzle capable of defining a spray pattern to impart a continuous film surface, depending on the substrate type present, of dielectric material. Optionally, positioned intermediate the nozzle and the substrate surface is a shutter/collimator 51, to further define the particle stream prior to its impact with the substrate surface. For example, in some instances, it is desired for the film surface to be conformal, while in other instances, it is desired for the film surface to be nonconformal, but nonetheless homogenous in constituency, and defect free, across the substrate surface to be coated. Preferably, the nozzle, in conjunction with the pressure differential, imparts powder velocities of between about 50 to 150 meters per second, and preferably about 100 meters per second so as to facilitate the generation of thermal energy at the particle-substrate interface sufficient to cause the powder particles to fuse with each other and with the substrate to produce a dielectric film. A myriad of nozzles are commercially available for this purpose, such as those from Bronson and Bratton, Burr Ridge, Ill.

In an embodiment of the invention, the substrate is mounted to prevent particles from being deposited on its back side or downstream side. In another embodiment of the invention, the substrate is positioned to allow particles to be deposited on the back side of the substrate. Dielectric deposition on both sides of the substrate allows capacitance to be built to both sides of the electrode, thereby doubling the capacitance density.

Downstream from the deposition chamber 46 is a filter 52 and downstream from the filter is a roughing pump 54. The filter removes fines (e.g. ceramic powder particles) and other particulates emanating from the deposition chamber 46 before they could damage the pump 54. The roughing pump is provided to establish and maintain the operation pressure differential of the system. In an embodiment, the roughing pump lowers the pressure inside the deposition chamber 46 so as to establish the pressure differential between the deposition chamber and the aerosol chamber 42. As noted supra, this configuration obviates the need for a valve 43 between the aerosol chamber 42 and deposition chamber 46. This valve-less configuration confers constant fluid communication between the two chambers during essentially the entire deposition process.

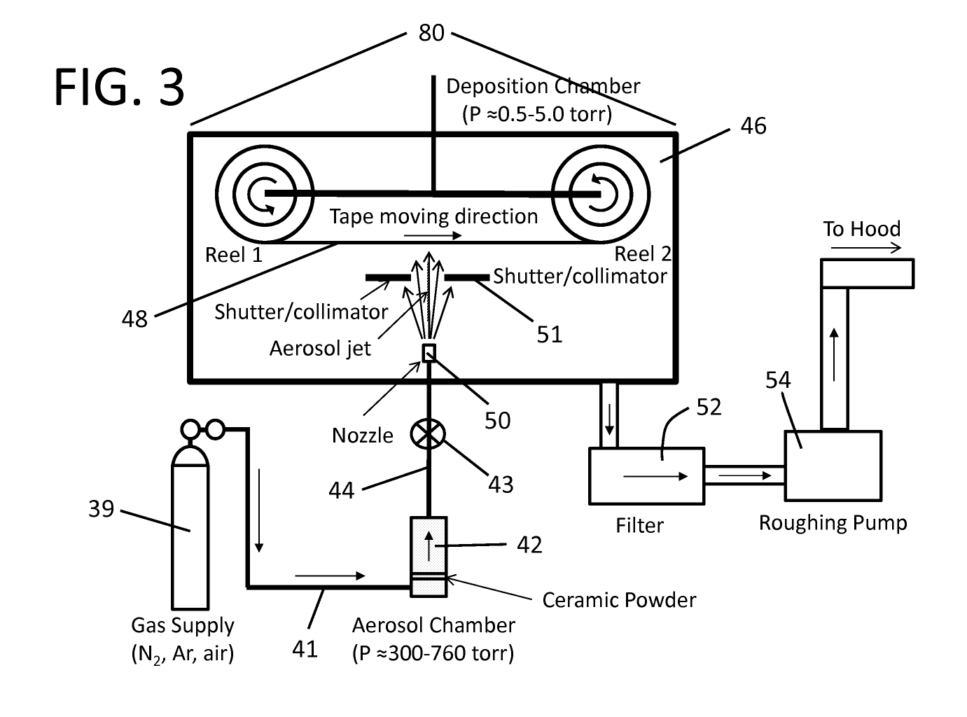

FIG. 3 is a schematic depiction of details of the invented aerosol deposition process in a reel-to-reel configuration 80. Thin base-metal foil (e.g. Al, Ni, Cu, Fe, etc) and metallized polymer film can be used as the substrate material 48. The base metal foil serves as both the bottom electrode and as mechanical support for the subsequent ceramic dielectric films.

Once the ceramic dielectric layer of appropriate thickness is deposited via AD, top electrodes are deposited on the dielectric layer by AD or one of the physical vapor deposition processes.

Optionally, a small clearance (uncoated area) 30 near the edge of the second (upwardly facing) surface 17 of the first electrode 12 is provided by masking. The clearance provides a means for establishing electrical contact between the first electrode and the rest of the circuit in which the capacitor resides.

The reel to reel process as depicted in FIG. 3 facilitates the fabrication of long-length (i.e., greater than approximately 8 meters) ceramic dielectric sheets by aerosol deposition.

A preferred process for generating the powders produces a preferred crystalline phase of dielectric material without the need for heating and milling the powder multiple times. (A preferred crystalline phase is single phase powder with substantially no impurities contained therein.) That process is as follows: To prepare Pb—La—Zr—Ti oxide (PLZT) materials (e.g., Pb_{0.92}La_{0.08}Zr_{0.52}Ti_{0.52}Ti_{0.48}Oₓ), an aqueous solution is made from Ti citrate and nitrates of Pb, La, and Zr. Concentrations of the cations are in the range 0.1-2.0 moles/liter. A fuel [e.g., citric acid (C₆H₈O₇), glycine (C₂H₅NO₂), or hydrazine (N₂H₄)] is added to the nitrate solution. Ammonium nitrate is added to the solution to adjust the fuel:oxidant ratio, which affects the combustion characteristics (i.e., peak temperature during combustion, speed of combustion). Fuel:oxidant ratios in the range 2:1 to 1:2 are used. The solution is heated to drive off water and initiate combustion. In order to prevent segregation of individual components as the water is removed, the fuel/nitrate solution is either poured into a beaker that is pre-heated on a hot plate or sprayed as a fine mist into a furnace that is pre-heated to 300-1200° C.

After synthesis, the PLZT powder is milled with ZrO₂ media in a volatile solvent (e.g., isopropyl alcohol) to produce the desired particle size. As an example, for 5 g of PLZT powder, 14.30 ml Pb(NO₃)₂, 2.54 ml La(NO₃)₃, 3.9 ml ZrO(NO₃)₂, 12.47 ml Ti Citrate solution, 26.61 g NH₄NO₃, and 20.17 g Citric Acid. The Pb conc. in Pb(NO₃)₂ was 220,150 mg/liter. The La conc. in La(NO₃)₃ was 72,150 mg/liter. The Zr conc. in ZrO(NO₃)₂ was 191,720 mg/liter. The Ti conc. in Ti citrate was 28,200 mg/liter. The Ti Citrate solution was prepared by slowly adding Ti Isopropoxide (97% purity) to 2 molar Citric Acid in deionized water. The Ti Citrate solution was made in a N₂-filled glovebox. ZrO(NO₃)₂ solution was purchased from Sigma-Aldrich.

Another process for generating the dielectrics are as follows: Powders of Pb—La—Zr—Ti oxide (PLZT) are made by combustion synthesis, a method for preparing fine (submicron) powders of multicomponent oxides. During combustion synthesis, an aqueous solution is prepared from nitrates of the constituent oxides. A fuel, such as glycine (C₂H₅O₂N), citric acid (C₆H₈O₇), or hydrazine (N₂H₄) is added to the nitrate solution, and the solution is heated either on a hot plate inside a fume hood or by spraying the solution into a heated furnace. When most of the water has evaporated and the temperature of the solution reaches ≈100° C., the solution ignites. During combustion of the solution, which lasts 5-10 minutes, PLZT powder is formed. The powder is then heated at 500° C. for 2 h in air to remove any residual carbon.

### EXAMPLE

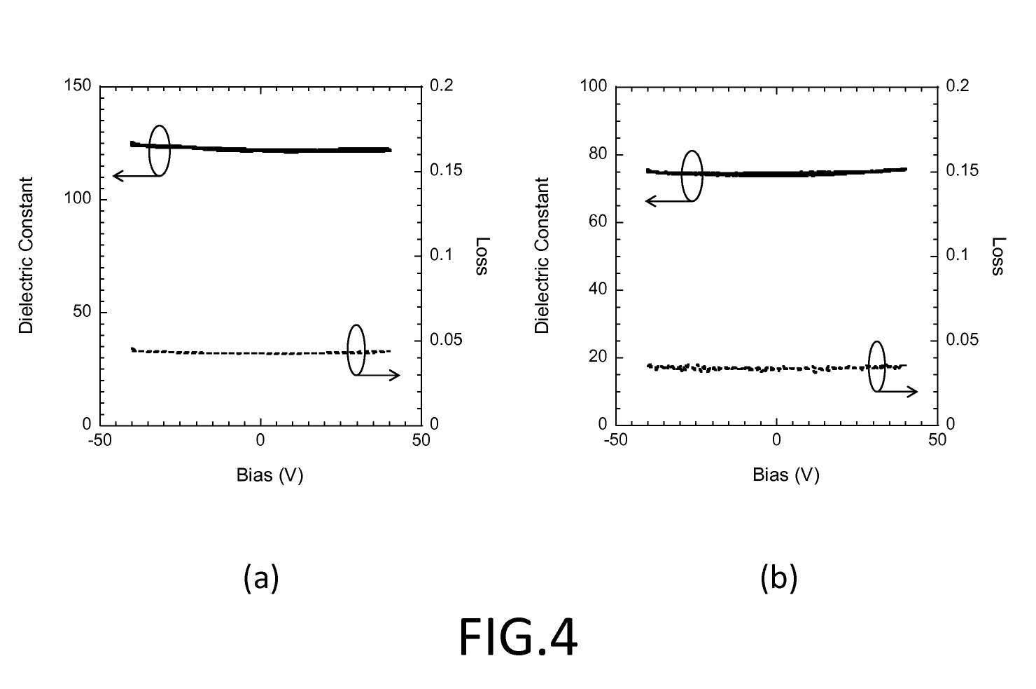

FIG. 4 comprises two graphs showing the dielectric properties as a function of bias field measured in PLZT films deposited by aerosol deposition on (a) platinized silicon substrate and (b) aluminum foil. Specifically, the graphs show dielectric properties as a function of bias voltage measured on a PLZT (approximately 1.5 μm thick) film deposited by aerosol deposition on platinized silicon substrate and aluminum foil. The solid upper line indicates dielectric constant as read along the left vertical scale in each graph.

The dashed lower line indicates the voltage loss as read along the right vertical scale in each graph.

It is noteworthy that no interceding oxide layer is necessary between the dielectric and the electrode surface. Both graphs depict date for a capacitor comprising direct contact of dielectric with metal electrodes.

Top electrodes of 250 μm in diameter were coated for dielectric property characterization.

Dielectric constants of about 120 and about 80 were measured on PLZT deposited on platinized silicon and aluminum foil respectively. (As discussed supra, the invention provides constructs exhibiting dielectric constants K of at least as high as about 80, and typically in a range of from about 80 to about 130. Constants of about 100 are typically achieved.) Platinized silicon wafers are commercially available. Suitable wafers were purchased from Nova Electronic Materials, LLC, Flower Mound, Tex. Suitable aluminum foil is also available commercially, such as standard cooking aluminum foil. The inventors obtained aluminum foil from Fisher Scientific, Pittsburgh, Pa.

The data in FIG. 4 shows that directly depositing high-k ceramic dielectric films on flexible substrates by a real-to-reel AD process is possible. Wound capacitors with high volumetric and gravimetric efficiencies result.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. While the dimensions and types of materials described herein are intended to define the parameters of the invention, they are by no means limiting, but are instead exemplary embodiments. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the terms “comprising” and “wherein.” Moreover, in the following claims, the terms “first,” “second,” and “third,” are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

The present methods can involve any or all of the steps or conditions discussed above in various combinations, as desired. Accordingly, it will be readily apparent to the skilled artisan that in some of the disclosed methods certain steps can be deleted or additional steps performed without affecting the viability of the methods. As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” “more than” and the like include the number recited and refer to ranges which can be subsequently broken down into subranges as discussed above. In the same manner, all ratios disclosed herein also include all subratios falling within the broader ratio.

One skilled in the art will also readily recognize that where members are grouped together in a common manner, such as in a Markush group, the present invention encompasses not only the entire group listed as a whole, but each member of the group individually and all possible subgroups of the main group. Accordingly, for all purposes, the present invention encompasses not only the main group, but also the main group absent one or more of the group members. The present invention also envisages the explicit exclusion of one or more of any of the group members in the claimed invention.

The embodiment of the invention in which an exclusive property or privilege is claimed is defined as follows:

1. A dielectric-conductive substrate construct comprising:
a. a conductive material having a first surface and a second surface;
b. a dielectric film directly contacting the first surface and substantially covering the first surface, wherein the second surface is exposed to the ambient environment.

2. The construct as recited in claim 1 wherein the dielectric is a ceramic selected from the group consisting of PLZT, PZT, BaTiO₃, (Ba,Sr)TiO₃, and combinations thereof.

3. The construct as recited in claim 1 wherein the conductive material comprises a flexible substrate selected from the group consisting of metal, nonmetal material, amorphous material, crystalline material, and combinations thereof.

4. The construct as recited in claim 1 wherein the conductive material comprises a continuous, elongated electrically conductive substrate with portions of the electrically conductive substrate removably received by a flexible support surface.

5. The construct as recited in claim 1 wherein the construct contains no interposed oxides between the substrate and the dielectric layer.

6. The construct as recited in claim 1 wherein the dielectric film is thermally fused to the conductive material.

7. The construct as recited in claim 1 wherein the dielectric film adheres to the conductive material.

8. A method for producing a two-component dielectric construct, the method comprising:
a. supplying a base metal; and
b. directly contacting a ceramic to the base metal to form a ceramic-metal interface while simultaneously preventing the formation of electrically insulative layers at the interface.

9. The method as recited in claim 8 wherein the layers comprise materials selected from the group consisting of nonferrous compounds, ferrous compounds, oxides, nitrides, and combinations thereof.

10. The method as recited in claim 8 wherein the ceramic is produced and provided having a single phase PLZT crystalline structure.

11. The method as recited in claim 8 wherein the base metal is aluminum, and the dielectric is PLZT.

12. The method as recited in claim 8 wherein the ceramic is applied as a powder to the base metal with a force to generate thermal energy at the surface of the base metal sufficient to cause the ceramic powder to coelesce and adhere to the metal.

13. The method as recited in claim 12 wherein the ceramic is applied to the base metal at room temperature via aerosol deposition.

14. The method as recited in claim 8 wherein the ceramic is contacted to the base metal at an impact velocity of greater than approximately 100 meters per second.

15. The method as recited in claim 8 wherein ceramic powder is contacted to the base metal so as to generate a thermal energy at the ceramic metal interface in an amount sufficient to cause the ceramic powder to fuse together.

16. The method as recited in claim 8 wherein the ceramic is contacted to the base metal at a velocity sufficient to cause the ceramic to fuse to the base metal.
